(19) United States
(12) Patent Application Publication
(10) Pub. No.: US 2026/0348009 A1
(43) Pub. Date: Nov. 5, 2026

(54) STRUCTURE INCLUDING METAL NITRIDE LAYER AND METHOD OF FORMING SAME

(71) Applicant: ASM IP Holding B.V., Almere (NL)

(72) Inventors: Venkata Surya Naga Raju Chava, Tempe, AZ (US); Andrew O'Reilly, Chandler, AZ (US); Lifu Chen, Phoenix, AZ (US); Balaji Kannan, Phoenix, AZ (US)

(21) Appl. No.: 19/656,421

(22) Filed: Apr. 23, 2026

Related U.S. Application Data
(60) Provisional application No. 63/795,958, filed on Apr. 28, 2025.

(51) Int. Cl. C23C 16/455; C23C 16/24; C23C 16/34; C23C 16/52

(52) U.S. Cl. CPC C23C 16/45553; C23C 16/24; C23C 16/34; C23C 16/45544; C23C 16/52

(57) ABSTRACT

Methods for forming a structure including metal nitride layer are disclosed. An exemplary method includes providing a substrate in a reaction chamber, performing a cyclical deposition process to form a metal nitride layer, and performing a soak process to form a cap layer. The cyclical deposition process comprises pulsing an organic silicon-containing reactant. The metal nitride layer formed by the method may have low resistivity, low oxidation, and high purity.

### CROSS-REFERENCE TO RELATED APPLICATIONS

This application is a nonprovisional of, and claims priority to and the benefit of, U.S. Provisional Patent Application No. 63/795,958, filed Apr. 28, 2025 and entitled “STRUCTURE INCLUDING METAL NITRIDE LAYER AND METHOD OF FORMING SAME,” which is hereby incorporated by reference herein.

### FIELD

The disclosure generally relates to methods of and apparatuses for forming structures, such as structures suitable for use in forming electronic devices. More particularly, examples of the disclosure relate to methods for forming a structure comprising a metal nitride layer and to structures formed using such methods.

### BACKGROUND

Metal nitride layers are widely used in the production of semiconductor devices for their chemical resistance, their relative hardness, low resistivity, and ability to withstand relatively high temperatures. However, with the scaling of semiconductor devices, higher quality metal nitrides (i.e., metal nitrides that have low oxidation, low impurities, and relatively high amounts of metal) are desired. The formation of high quality metal nitrides has presented challenges. Therefore, there exists a desire for improved method for forming metal nitride layers with low impurities, low oxidation, and low resistivity.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Various examples described herein relate to methods for forming a structure that includes a metal nitride layer. As set forth below, methods described herein may be used in the fabrication of electronic devices, such as semiconductor devices. Exemplary methods may produce a metal nitride layer with very low resistivity at small thicknesses (e.g., less than 110 μΩ·cm at a thickness of about 200 Angstroms or less) and may produce a metal nitride layer with relatively low oxidation. Advantageously, additionally or alternatively, exemplary methods as described herein may be done a relatively low temperature (e.g., less than 500 °C) with a (e.g., thermal) cyclical deposition process.

According to one or more embodiments, a method of forming a structure is provided. An exemplary method includes providing a substrate in a reaction chamber, performing a cyclical deposition process, optionally performing an ammonia treatment, and performing a soak process. Performing the cyclical deposition process may form a metal nitride layer on a surface of the substrate. Performing the soak process may form a cap layer (e.g., directly) on the metal nitride layer.

In some embodiments, the surface of the substrate includes one or more features, such as trenches, gaps, or the like. The method may form the metal nitride in the one or more features.

In some embodiments, performing the cyclical deposition process includes pulsing a metal precursor, pulsing an organic silicon-containing reactant, pulsing a nitrogen reactant, and optionally performing a purge. The organic silicon-containing reactant may act as a reducing agent.

The organic silicon-containing reactant includes carbon and silicon. In some embodiments, the organic silicon-containing reactant comprises carbon, silicon, and nitrogen. In some embodiments, the organic silicon-containing reactant includes a carbon ring structure. In some embodiments, the organic silicon-containing reactant includes a cyclohexane ring. In some embodiments, the organic silicon-containing reactant includes a heterocyclic compound. In some embodiments, the organic silicon-containing reactant includes between 6 and 30 carbon atoms, or between 9 and 18 carbon atoms.

In some embodiments, performing the ammonia treatment includes providing ammonia (NH₃) to the reaction chamber for a treatment period after performing the cyclical deposition process and before performing the soak process.

In some embodiments, performing the soak process includes providing a silicon precursor to the reaction chamber for a soak period. The soak process may form a (e.g. silicon) cap layer on the metal nitride layer. The cap layer may prevent damage or oxidation of the underlying metal nitride layer. In some embodiments, the method may form a metal nitride layer with a cap layer in one or more features on a surface of a substrate.

In accordance with further examples of the disclosure, a device is formed using a method and/or includes a structure as described herein.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

A more complete understanding of the embodiments of the present disclosure may be derived by referring to the detailed description and claims when considered in connection with the following illustrative figures.

FIG. 1 illustrates a method for forming a structure, in accordance with one or more embodiments of the disclosure;

FIG. 2 illustrates a method for performing a cyclical deposition process in accordance with one or more embodiments of the disclosure;

FIG. 3 illustrates an example of a substrate processing apparatus in accordance with one or more examples of the disclosure;

FIG. 4 illustrates an example of a structure that can form part of a device in accordance with one or more examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to necessarily limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the singular and plural forms as well, unless the context indicates otherwise.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. By way of example, a substrate can include silicon or silicon germanium. In some cases, the substrate can include an oxide (e.g., silicon oxide).

The terms “precursor” and “reactant” can refer to molecules or compounds that participate in a chemical reaction that produces a layer or deposited material. A precursor typically contains portions that are at least partly incorporated into a layer. Such resulting portions may be deposited on a substrate to form a film as disclosed herein. A reactant may be a compound that is incorporated into the layer or that is not incorporated into the resulting layer to a significant extent. In some cases, the term reactant can be used interchangeably with the term precursor.

As used herein, a “metal precursor” includes a gas or a material that can become gaseous and that can be represented by a chemical formula that includes one or more metals.

As used herein, a “silicon precursor” includes a gas or a material that can become gaseous and that can be represented by a chemical formula that includes silicon.

As used herein, a “nitrogen reactant” includes a gas or a material that can become gaseous and that can be represented by a chemical formula that includes nitrogen.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous- or not. Further, a single film or layer can be formed using one or more deposition cycles.

As used herein, the term “purge” can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be affected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

As used herein, the term “structure” can refer to a partially or completely fabricated device structure. By way of examples, a structure can be a substrate or include a substrate with one or more layers and/or features formed thereon.

As used herein, the term “overlying” can refer to a film (e.g., directly) on top of another film.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. For example, values of variables may include +/−20%, or +/−10%, or +/−5%, or +/−1%, or +/−0% of the value of the listed variable. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

A carrier and/or inert gas can be (e.g., continuously) co-flowed throughout any steps or sub-steps of any methods described herein. By way of example, a carrier and/or an inert gas can be one or more of helium, argon, or nitrogen.

Various steps of methods described herein can be performed within a single reaction chamber or can be performed in multiple reaction chambers, such as reaction chambers of a cluster tool. In some embodiments, the method may take place in a single reaction space. In some embodiments, one or more steps or substeps of methods described herein may take place in different reaction spaces and/or different reaction chambers.

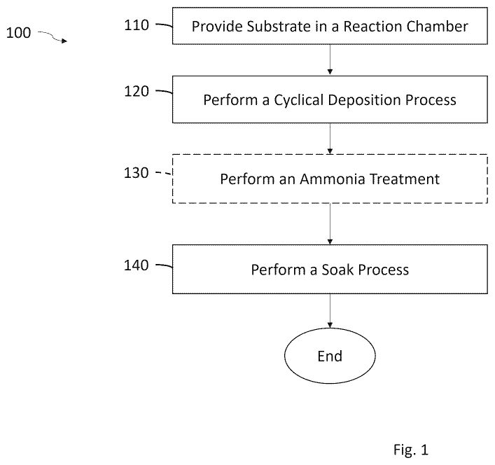

FIG. 1 illustrates a method 100 for forming a structure in accordance with exemplary embodiments of the disclosure. Method 100 includes providing a substrate within a reaction chamber (step 110), performing a cyclical deposition process (step 120), optionally performing an ammonia treatment (step 130), and performing a soak process (step 140). In some embodiments, no oxygen, oxidizing compounds, or compounds comprising oxygen are provided to the reaction chamber during method 100.

During step 110, a substrate is provided into a reaction space in a reaction chamber. In accordance with examples of the disclosure, the reaction chamber can form part of a chemical vapor deposition reactor, such as a chemical vapor deposition (CVD) reactor, an atomic layer deposition (ALD) reactor, or the like.

During step 110, the substrate can be brought to a desired temperature and/or the reaction space can be brought to a desired pressure, such as a temperature and/or pressure suitable for subsequent steps. The method can be performed at relatively low temperatures to stay within a thermal budget for processing of a substrate. By way of examples, a temperature (e.g., of a substrate, a substrate support, or an environment) within a reaction space can be between about 0 °C and about 500 °C, or between about 250 °C and about 425 °C, or between about 300 °C and about 400 °C, or between about 325 °C and 375 °C. A pressure within a reaction space can be less than 760 torr, or between about 1 torr and 500 torr, or between about 1 torr and about 100 torr.

In some embodiments, the substrate may comprise one or more features on a surface of the substrate. The features may be gaps, trenches, or the like. The one or more features may have an aspect ratio greater than 1, or greater than 10, or between about 5 and about 25. The one or more features may have a depth greater than 10 nm, or greater than 30 nm, or between about 10 nm and 100 nm. Additionally or alternatively, the one or more features may have a width between about 5 nm and about 100 nm, or between about 10 nm and about 50 nm.

The method 100 continues with performing a cyclical deposition process (step 120). In some embodiments, the cyclical deposition process is an atomic layer deposition process. In some embodiments, performing the cyclical deposition process forms a metal nitride layer (e.g., directly) on the surface of the substrate. In some embodiments, performing the cyclical deposition process forms a metal nitride layer (e.g., directly) in the one or more features. The metal nitride layer comprises one or more metals and nitrogen. In some embodiments, the metal nitride layer comprises one or more transition metals. In some embodiments, the metal nitride layer comprises one or more of titanium, vanadium, niobium, zirconium, or molybdenum. In some embodiments, the metal nitride layer has low impurities (e.g., the metal nitride layer comprises less than about 5 at % of elements other than a metal and nitrogen, or less than about 3 at % of elements other than a metal and nitrogen).

In some embodiments, the metal nitride layer has a thickness less than about 200 Angstroms, or between about 3 Angstroms to about 30 Angstroms, or between about 5 Angstroms and about 20 Angstroms, or between about 7 Angstroms and about 15 Angstroms. In some embodiments, the metal nitride layer has a relatively low resistivity for very thin films, such as films with a thickness below 250 Angstroms. In some embodiments, the metal nitride layer has a resistivity of less than 400 μΩ·cm, or less than 200 μΩ·cm, or less than 125 μΩ·cm, or less than 110 μΩ·cm for thin layers with a thickness of about 200 Angstroms. In some embodiments, the metal nitride layer has a resistivity of less than 750 μΩ·cm, or less than 400 μΩ·cm, or less than 325 μΩ·cm, or less than 310 μΩ·cm for thin layers with a thickness of about 40 Angstroms. A person with ordinary skill in the art will recognize that thin metal nitride films formed by the disclosed methods of other thicknesses will have different resistances. In some embodiments, the metal nitride layer has a roughness less than about 3 Angstroms or less than about 2.5 Angstroms.

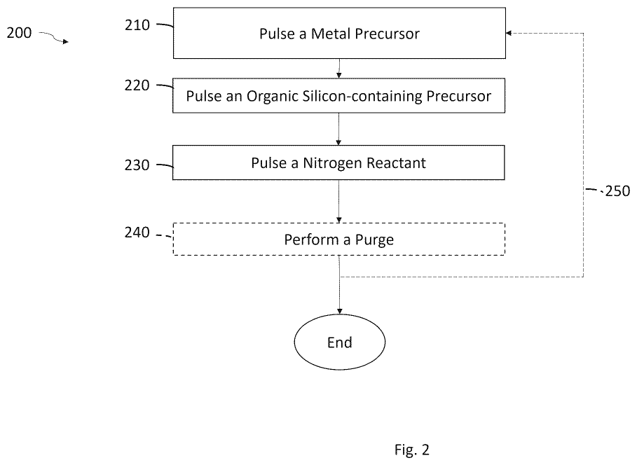

FIG. 2 illustrates a method 200 suitable for step 120 in FIG. 1. Method 200 comprises performing a cyclical deposition process. Method 200 comprises pulsing a metal precursor (step 210), pulsing an organic silicon-containing reactant (step 220), pulsing a nitrogen reactant (step 230), optionally performing a purge (step 240), and optionally repeating the steps one or more times (loop 250). In some cases, the steps 210-240 of method 200 may be performed in any order. In some cases, the steps 210-230 are performed in sequence of step 210, step 220, and step 230. This sequence may produce a high quality metal nitride layer with low resistivity. Each step 210-240 of method 200 may be performed once or a plurality of times before proceeding to the next step. In some embodiments, a purge, such as purge 240, is performed after one or more of the steps 210-230 of pulsing a metal precursor 210, pulsing an organic silicon-containing reactant 220, and pulsing a nitrogen reactant 230. In some embodiments, each pulse of precursor or reactant (steps 210-230) comprises starting and then ceasing a flow of the precursor or reactant into the reaction chamber before a subsequent step. In some embodiments, steps 210-230 may overlap. In some embodiments, pulsing a nitrogen reactant comprises continuously providing the nitrogen reactant to the reaction chamber during one or more steps of method 200 or throughout method 200. In some embodiments, no oxygen, oxidizing compounds, or compounds comprising oxygen are provided to the reaction chamber during the method 200.

In some embodiments, the metal precursor comprises one or more transition metals. In some embodiments, the metal precursor comprises one or more of Mo, Vn, Ti, Nb, or Zr. In some embodiments, the metal precursor comprises a metal halide or a metalorganic. By way of examples, the metal precursor may be or comprise one or more of titanium tetrachloride, tetrakis(dimethylamido)titanium, vanadium tetrachloride, molybdenum chloride, vanadium oxytrichloride, Bis(t-butylimido)bis(dimethylamino)molybdenum(VI), and zirconium(IV) tetrachloride.

The nitrogen reactant comprises nitrogen. By way of examples, the nitrogen reactant may be or comprise nitrogen (N₂), ammonia (NH₃), hydrazine (N₂H₄), and/or nitrogen radicals.

The organic silicon-containing reactant comprises carbon and silicon. In some embodiments, the organic silicon-containing reactant comprises carbon, silicon, and nitrogen. In some embodiments, the organic silicon-containing reactant comprising at least one silicon-carbon bond. In some embodiments, the organic silicon-containing reactant comprises a carbon ring structure. In some embodiments, the organic silicon-containing reactant comprises a cyclohexane ring. In some embodiments, the organic silicon-containing reactant comprises a heterocyclic compound. In some embodiments, the organic silicon-containing reactant comprises an azine compound. In some embodiments, the organic silicon-containing reactant includes between 6 and 30 carbon atoms, or between 9 and 18 carbon atoms. In some embodiments, the organic silicon-containing reactant includes at least two silicon atoms.

In some embodiments, the organic silicon-containing reactant includes at least one ligand with the formula of —Si(R¹)₃, where each R¹ is independently selected from H or C1-C3 alkyl groups. In some embodiments, the organic silicon-containing reactant includes a compound with formula (i):

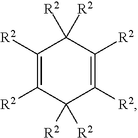

where each R² is independently selected from H, C1-C3 alkyl groups, or ligands with the formula of —Si(R¹)₃, where each R¹ is independently selected from H or C1-C3 alkyl groups. In some embodiments, the organic silicon-containing reactant includes a compound with formula (ii):

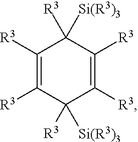

where each R³ is independently selected from H or C1-C3 alkyl groups. By way of examples, the organic silicon-containing reactant may be represented by formula (iii):

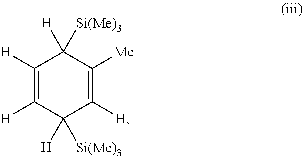

where Me is a methyl group.

In some embodiments, the organic silicon-containing reactant comprises a compound with formula (iv):

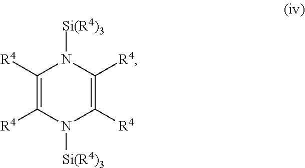

where each R⁴ is independently selected from H, C1-C3 alkyl groups. In some embodiments, the organic silicon-containing reactant comprises a compound with formula (v):

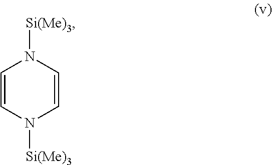

where Me is a methyl group.

Not to be bound by theory, the use of the organic silicon-containing reactant is thought to reduce a chemisorbed metal precursor component and form a metallic layer on the surface of the substrate. Advantageously, the reaction produces a neutral organic compound without the production of ions or salts. It is thought that the use of the organic silicon-containing reactant produces a metallic layer with relatively higher purity and lower resistivity that may form a high quality metal nitride layer after being exposed to the nitrogen reactant. Further, the method may prevent oxidation of the metal nitride layer by not using compounds comprising oxygen.

Turning back to FIG. 1, the method 100 continues with optionally performing an ammonia treatment 130. In some embodiments, the ammonia treatment comprises providing ammonia to the reaction chamber for a treatment period. In some embodiments, the treatment period has a duration of about 0.1 seconds to about 10 seconds, or between about 1 second and about 5 seconds. Not to be bound by theory, the ammonia treatment may prime the underlying (e.g., metal nitride) layer for subsequent formation of an overlying layer. In some embodiments, the reaction chamber has a temperature of about 0 °C and about 500 °C, or between about 250 °C and about 425 °C, or between about 300 °C and about 400 °C, or between about 325 °C and 375 °C, and a pressure of about 1 torr and 500 torr, or between about 1 torr and about 100 torr during the ammonia treatment (step 130). In some embodiments, the ammonia treatment (step 130) is performed after performing the cyclical deposition process (step 120) and before performing the soak process (step 140).

Method 100 continues with performing a soak process 140. The soak process 140 comprises providing a silicon precursor to the reaction chamber. In accordance with examples of the disclosure, the soak process comprises providing the silicon precursor to the reaction chamber while not removing the silicon precursor with a removal pump or reducing a removal rate (e.g., by closing valves for gas removal) for a load period LP. This results in a pressure buildup of the silicon precursor in the reaction chamber. This build up may be terminated when the pressure in the reaction chamber reaches a desired pressure. Alternatively, there may be a pressure release valve that opens when the pressure in the reaction chamber increases above a predetermined maximum, which may also end the pressure load period LP.

Subsequently, the silicon precursor may be maintained residing stationary or substantially stationary or relatively stationary in the reaction chamber while not providing or removing any silicon precursor for a soak period SP. This may be done by closing reactor chamber valves. When the reaction chamber is constructed and arranged to accommodate a single substrate, the load period LP can be between 1 and 3000 seconds, between 3 and 1000 seconds, or between 5 and 500 seconds; and the soak period SP can be between 10 and 9000 seconds, between 50 and 5000 seconds, or between 100 and 1000 seconds, or between about 200 seconds and about 300 seconds. In some cases, a flowrate of gas from the reaction chamber to a vacuum source during the soak period is less than a flowrate of gas from the reaction chamber to the vacuum source during the cyclical deposition process. During the soak process, the silicon precursor may react with a surface of the metal nitride layer. The silicon precursor can be purged from the reaction chamber (e.g., during a flush period or in subsequent purges in subsequent steps.)

In some embodiments, the silicon precursor comprises a (e.g., hydrogenated) silane. By way of examples, the silicon precursor may be or include silane (SiH4), disilane (Si2H6), trisilane (Si₃H₈), silicon tetrachloride (SiCl₄), dichlorosilane (SiH₂Cl₂), hexachlorodisilane (Si₂Cl₆), or octachlorotrisilane (Si₃Cl₈).

The formation of a cap layer on the metal nitride layer may allow for longer storage or transfer throughout environments with ambient oxygen without oxidation or with reduced oxidation of the underlying metal nitride layer.

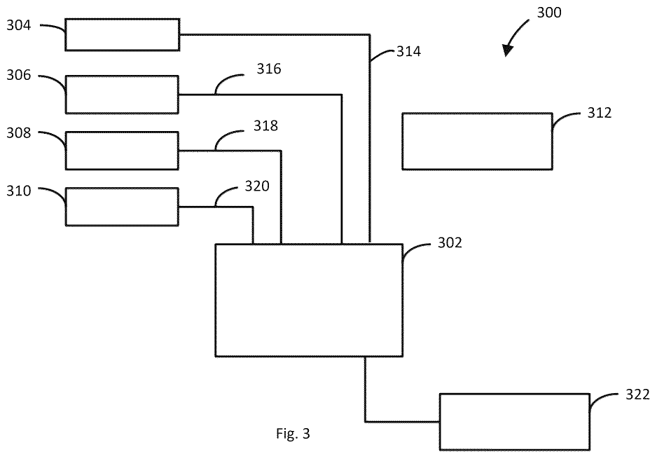

FIG. 3 illustrates an example of a substrate processing apparatus 300 in accordance with one or more examples of the disclosure. Apparatus 300 can be used to perform a method as described herein and/or form a structure or device portion as described herein.

In the illustrated example, apparatus 300 includes one or more reaction chambers 302, a metal precursor gas source 304, an organic silicon-containing reactant source 306, a nitrogen reactant source 308, a silicon precursor gas source 310, an exhaust source 322, and a controller 312.

Reaction chamber 302 can include any suitable reaction chamber, such as an atomic layer deposition (ALD) or chemical vapor deposition (CVD) reaction chamber.

Metal precursor gas source 304 can include a vessel and one or more precursors comprising a metal (such as the metal precursors as described herein)—alone or mixed with one or more carrier (e.g., inert) gases. Organic silicon-containing reactant source 306 can include a vessel and one or more reactants, precursors, or gases comprising an organic silicon-containing reactant as described herein-alone or mixed with one or more carrier (e.g., inert) gases. Nitrogen reactant source 308 can include a vessel and one and/or more reactants comprising nitrogen, as described herein-alone or mixed with one or more carrier (e.g., inert) gases. Silicon precursor gas source 310 can include a vessel and one or more of silicon precursors as described herein-alone or mixed with one and/or more carrier gases. Although illustrated with four gas sources 304-310, apparatus 300 can include any suitable number of gas sources, including gas sources for an inert gas, such as helium, argon, and/or nitrogen. Gas sources 304-310 can be coupled to reaction chamber 302 via lines 314-320, which can each include flow controllers, valves, heaters, and the like.

Exhaust source 322 can include one or more vacuum pumps.

Controller 312 includes electronic circuitry and software to selectively operate valves, manifolds, heaters, pumps, and other components included in the apparatus 300. Such circuitry and components operate to introduce precursors, reactants, and gases from the respective sources 304-310. Controller 312 can control timing of gas pulse sequences, temperature of the substrate and/or reaction chamber, pressure within the reaction chamber, and various other operations to provide proper operation of the apparatus 300. Controller 312 can include control software to electrically or pneumatically control valves to control flow of precursors, reactants, and purge gases into and out of the reaction chamber 302. Controller 312 can include modules such as a software or hardware component, e.g., a FPGA or ASIC, which performs certain tasks. A module can advantageously be configured to reside on the addressable storage medium of the control system and be configured to execute one or more processes or methods, as described herein.

Other configurations of apparatus 300 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 302. Further, as a schematic representation of a system, many components have been omitted for simplicity of illustration, and such components may include, for example, various valves, manifolds, purifiers, heaters, containers, vents, and/or bypasses.

During operation of apparatus 300, substrates, such as semiconductor wafers (not illustrated), are transferred from, e.g., a substrate handling system to reaction chamber 302. Once substrate(s) are transferred to reaction chamber 302, one or more gases from gas sources 304-310, such as precursors, reactants, carrier gases, and/or purge gases, are introduced into reaction chamber 302.

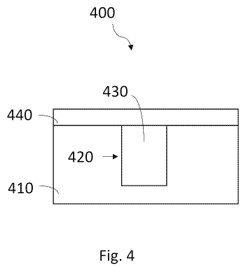

FIG. 4 illustrates a structure/a portion of a device 400 in accordance with additional examples of the disclosure. Device or structure 400 includes a substrate 410 comprising a feature 420, a metal nitride layer 430 in the feature 420, and a cap layer 440 directly overlying the metal nitride layer 430. In some embodiments, the substrate 410 comprises a semiconductor, such as silicon or silicon germanium. In some embodiments, the feature 420 is a gap or trench. In some embodiments, the feature 420 has an aspect ratio greater than 1, or greater than 10, or between about 5 and about 25. In some embodiments, the metal nitride layer 430 comprises one or more of titanium, vanadium, niobium, zirconium, or molybdenum. In some embodiments, the metal nitride layer 430 has a thickness between about 10 Angstroms and about 200 Angstroms, or between about 20 Angstroms and 100 Angstroms. In some embodiments, the metal nitride layer has a resistivity less than 400 μΩ·cm, or less than 325 μΩ·cm, or less than 310 μΩ·cm for thin layers with a thickness of about 40 Angstroms. In some embodiments, the cap layer 440 comprises silicon. In some embodiments, the cap layer has a thickness between about 2 and 30 Angstroms, or between about 5 and about 15 Angstroms.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a structure, the method comprising:
providing a substrate in a reaction chamber;
performing a cyclical deposition process, a cycle of the cyclical deposition process comprising:
pulsing a metal precursor,
pulsing an organic silicon-containing reactant, and
pulsing a nitrogen reactant; and
performing a soak process, wherein the soak process comprises providing a silicon precursor to the reaction chamber for a soak period.

2. The method of claim 1, wherein the metal precursor comprises a metal halide.

3. The method of claim 2, wherein the metal precursor comprises one or more of Mo, Vn, Ti, Nb, or Zr.

4. The method of claim 1, wherein the nitrogen reactant comprises one or more of nitrogen (N₂), ammonia (NH₃), hydrazine (N₂H₄), and/or nitrogen radicals.

5. The method of claim 1, wherein the organic silicon-containing reactant comprises a heterocyclic compound.

6. The method of claim 1, wherein the organic silicon-containing reactant comprises a compound with formula (i): 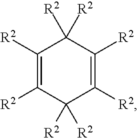
where each R² is independently selected from H, C1-C3 alkyl groups, or ligands with a formula of —Si(R¹)₃, wherein each R¹ is independently selected from H or C1-C3 alkyl groups.

7. The method of claim 1, wherein the organic silicon-containing reactant comprises a compound with formula (ii): 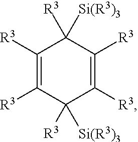
wherein each R³ is independently selected from H or C1-C3 alkyl groups.

8. The method of claim 1, wherein the organic silicon-containing reactant comprises a compound with formula (iii): 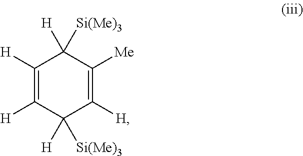
wherein Me is a methyl group.

9. The method of claim 1, wherein the silicon precursor comprises one or more of silane (SiH4), disilane (Si2H6), trisilane (Si₃H₈), silicon tetrachloride (SiCl₄), dichlorosilane (SiH₂Cl₂), hexachlorodisilane (Si₂Cl₆), or octachlorotrisilane (Si₃Cl₈).

10. The method of claim 1, wherein the soak period has a duration of 50 and 5000 seconds.

11. The method of claim 1, wherein the substrate comprises one or more features on a surface of the substrate, and wherein the method forms a metal nitride in the one or more features.

12. The method of claim 1, wherein the cyclical deposition process forms a metal nitride layer, and wherein the soak process forms a cap layer comprising silicon.

13. The method of claim 12, wherein the cap layer has a thickness less than 30 Angstroms.

14. The method of claim 12, wherein the metal nitride layer has a thickness less than about 200 Angstroms.

15. The method of claim 1, wherein a temperature of the reaction chamber during the cyclical deposition process and the soak process is in the range of about 250 °C to about 500 °C.

16. The method of claim 1, wherein the organic silicon-containing reactant comprises a compound with formula (iv): 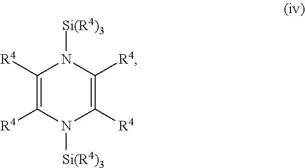
wherein each R⁴ is independently selected from H and C1-C3 alkyl groups.

17. The method of claim 1, wherein oxygen or an oxidizing compound is not provided to the reaction chamber during the method.

18. A method of forming a structure, the method comprising:
providing a substrate in a reaction chamber;
forming a metal nitride layer on a surface of the substrate, wherein forming the metal nitride layer comprises:
pulsing a metal halide precursor, and
pulsing a nitrogen reactant comprising one or more of ammonia or nitrogen (N₂); and
forming a cap layer directly on the metal nitride layer, wherein the cap layer comprises silicon.

19. The method of claim 18, wherein forming the metal nitride layer further comprises pulsing an organic silicon-containing reactant.

20. A substrate processing apparatus for forming a structure, the apparatus comprising:
a reaction chamber;
a susceptor in the reaction chamber configured to hold a substrate;
a metal precursor source configured to provide a metal precursor into the reaction chamber;
an organic silicon-containing reactant source configured to provide organic silicon-containing reactant into the reaction chamber;
a nitrogen reactant source configured to provide a nitrogen reactant into the reaction chamber;
a silicon precursor source configured to provide a silicon precursor into the reaction chamber; and
a controller comprising an addressable storage medium, wherein the controller is configured to control gas flow into the reaction chamber to:
perform a cyclical deposition process and a soak process after the cyclical deposition process,
wherein the cyclical deposition process comprises:
pulsing the metal precursor,
pulsing the organic silicon-containing reactant, and
pulsing the nitrogen reactant; and
wherein the soak process comprises providing the silicon precursor to the reaction chamber for a soak period.
